(19) United States
(12) Patent Application Publication
(10) Pub. No.: US 2025/0334609 A1
(43) Pub. Date: Oct. 30, 2025

(54) ELECTRICAL CONNECTING APPARATUS

(71) Applicant: KABUSHIKI KAISHA NIHON MICRONICS, TOKYO (JP)

(72) Inventors: RYOSUKE SHUTO, TOKYO (JP); KENTARO TANAKA, TOKYO (JP)

(73) Assignee: KABUSHIKI KAISHA NIHON MICRONICS, TOKYO (JP)

(21) Appl. No.: 18/868,460

(22) PCT Filed: Jul. 11, 2023
(86) PCT No.: PCT/JP2023/025541

§ 371 Date: Nov. 22, 2024

(30) Foreign Application Priority Data
Jul. 28, 2022 (JP) 2022-120167

(51) Int. Cl. G01R 1/073

(52) U.S. Cl. CPC G01R 1/0735; G01R 1/07342

(57) ABSTRACT

The flatness of a board on which a plurality of probes are mounted is adjusted to improve the electrical contact of the probes with the electrode terminals of a test subject. The electrical connecting apparatus of the present disclosure includes: a wiring board electrically connected to a testing device; a probe board provided on a bottom surface side of the wiring board and having one or more probe attachment parts on which a plurality of probes are mounted for each electrode terminal of a test subject that has one or more electrode terminals, the plurality of probes being electrically contacted with the corresponding electrode terminals; and a cover member that adjusts flatness of the probe board and has at least one or more flatness adjustment mechanisms provided corresponding to each of the probe attachment parts of the probe board.

### TECHNICAL FIELD

The present disclosure relates to an electrical connecting apparatus and can be applied to an electrical connecting apparatus used, for example, in the electrical testing of semiconductor integrated circuits.

### BACKGROUND

The electrical testing of semiconductor integrated circuits (test subjects) on a semiconductor wafer uses a testing device (tester) that has a probe card with a plurality of probes (electrical contactors) attached to a test head. Then, the electrode terminals of the semiconductor integrated circuit are electrically contacted with the probes. The tester supplies electrical signals to the semiconductor integrated circuit through the probes, and the semiconductor integrated circuit outputs the electrical signals to the tester through the probes. In this way, the electrical testing of the semiconductor integrated circuit is performed.

There are various types of probe cards, and one type is the one described in PTL 1 and the probe card shown in FIG. 9. Here, for convenience of explanation, the structure of a conventional probe card 100 will be explained using FIG. 9.

The probe card 100 in FIG. 9 includes a wiring board 11 and a multilayer wiring board 12 having a plurality of probes on the bottom side of the wiring board 11. A number of bonding members (solder balls) 31 bonds the wiring board 11 and the multilayer wiring board 12. In addition, a reinforcing member 13 and a cover member 94 are provided on the top surface of the wiring board 11 of the probe card 100, and a block member 95 is provided at a position corresponding to a probe pad area 121 of the multilayer wiring board 12 to support the load of the probe.

### CITATION LIST

### Patent Literature

PTL1: WO2019/021749A

### SUMMARY

### Technical Problem

However, when the multilayer wiring board 12 and the wiring board 11 are bonded by the bonding member 31, the application of heat may cause the multilayer wiring board 12 to warp. In addition, the multilayer wiring board 12 may be bonded to the wiring board 11 in an inclined state. In such a case, the height of the probe mounted on the probe pad area 121 of the multilayer wiring board 12 varies, and there is a possibility that the probe cannot correctly contact the electrode terminal.

Therefore, in order to improve the electrical contact of the probes with the electrode terminals of a test subject, an electrical connecting apparatus capable of adjusting the flatness of a board (for example, a multilayer wiring board) on which a plurality of probes are mounted is required.

### Solution to Problem

In order to solve such a problem, the electrical connecting apparatus of the present disclosure includes: (1) a wiring board electrically connected to a testing device; (2) a probe board provided on a bottom surface side of the wiring board and having one or more probe attachment parts on which a plurality of probes are mounted for each electrode terminal of a test subject that has one or more electrode terminals, the plurality of probes being electrically contacted with the corresponding electrode terminals; and (3) a cover member that adjusts flatness of the probe board and has at least one or more flatness adjustment mechanisms provided corresponding to each of the probe attachment parts of the probe board.

### Advantageous Effects

According to the present disclosure, the flatness of a board on which a plurality of probes are mounted can be adjusted to improve the electrical contact of the probes with the electrode terminals of a test subject.

### BRIEF DESCRIPTION OF DRAWINGS

FIG. 1 is a diagram showing an outline of the main configuration of an electrical connecting apparatus according to an embodiment.

FIG. 2 is a plan view of the electrical connecting apparatus according to the embodiment.

FIG. 3 is a bottom view of the electrical connecting apparatus according to the embodiment.

FIG. 4 is a diagram showing the configuration of a multilayer wiring board provided on the bottom surface of a wiring board according to an embodiment.

FIG. 5 is a diagram showing the arrangement of an indenter 22 on the wiring board according to the embodiment.

FIG. 6 is a diagram showing the top surface of a cover member according to an embodiment.

FIG. 7 is a perspective diagram of an indenter according to an embodiment as viewed from below.

FIG. 8 is a diagram showing the results of the flatness measurement of a multilayer wiring board in an embodiment.

FIG. 9 is a diagram showing an outline of the configuration of a conventional electrical connecting apparatus.

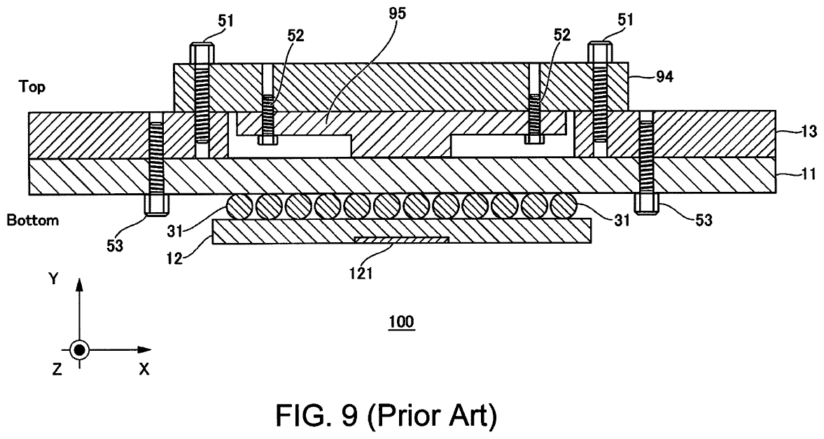

FIG. 10 is a diagram showing the configuration of an indenter according to a modified embodiment (part 1).

FIG. 11 is a diagram showing the configuration of an indenter according to a modified embodiment (part 2).

### DETAILED DESCRIPTION

### (A) Embodiment

Hereinafter, an embodiment of the electrical connecting apparatus according to the present disclosure will be described in detail with reference to the drawings.

In the present embodiment, each of a plurality of semiconductor integrated circuits formed on a semiconductor wafer is treated as a test subject. In addition, the present disclosure illustrates a case where the electrical connecting apparatus is applied to a probe card used in a testing device that tests the electrical characteristics of such a test subject.

“Flatness” generally refers to the degree of deviation of a planar shape from a geometrically correct plane. In other words, flatness is a numerical value indicating the smoothness (uniformity) of a plane and how accurately a surface should be flat. For example, the value of the vertical distance between the plane, including the most protruding part of the planar shape, and the plane, including the most recessed part, can be taken as flatness. For example, in this disclosure, “flatness” is intended to include not only the overall flatness of the probe board but also the flatness of a partial region of the probe board where a plurality of probes are arranged (for example, the probe region).

### (A-1) Configuration of Embodiment

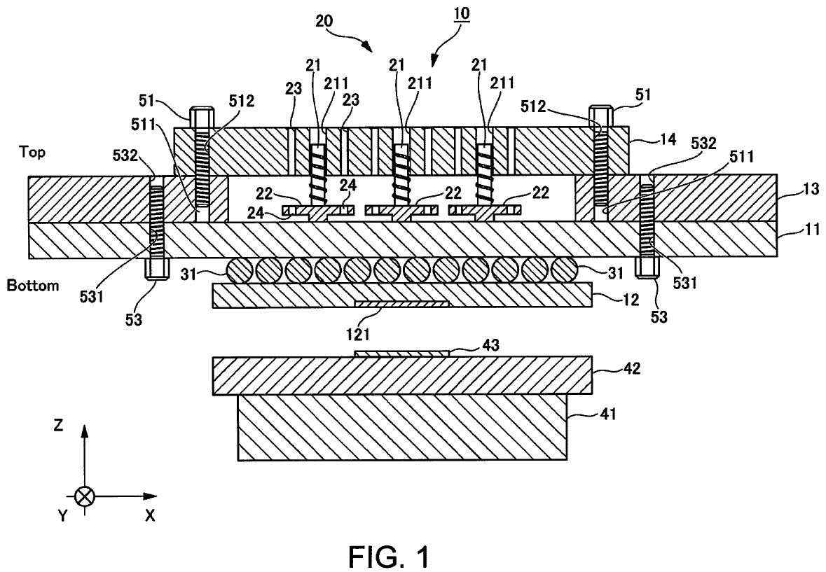

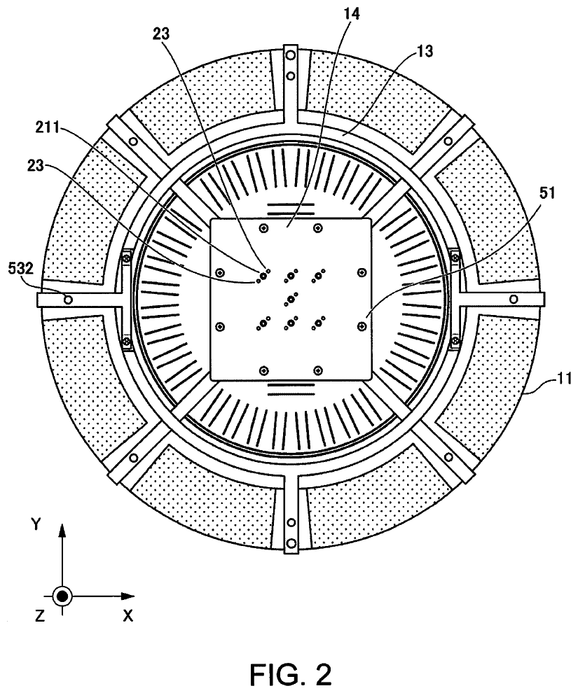

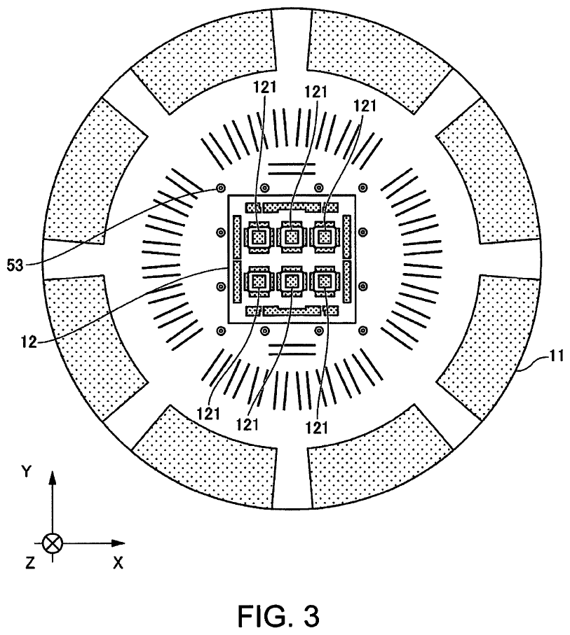

FIG. 1 is a diagram showing an outline of the main configuration of the electrical connecting apparatus according to the embodiment. FIG. 2 is a plan view of the electrical connecting apparatus, and FIG. 3 is a bottom view of the electrical connecting apparatus.

In FIGS. 1 to 3, the electrical connecting apparatus 10 according to the embodiment includes a wiring board 11, a multilayer wiring board 12, a reinforcing member 13, and a cover member 14 having a flatness adjustment mechanism 20.

The electrical connecting apparatus 10 is provided in a test header of a testing device when performing the electrical testing of a plurality of test subjects 43 formed on a semiconductor wafer. The multilayer wiring board 12 of the electrical connecting apparatus 10 has a plurality of electrical contactors (probes). When performing electrical testing, each probe of the electrical connecting apparatus 10 is electrically contacted with a corresponding electrode terminal of the test subject 43, and the testing device performs the electrical testing of the test subject 43.

The test subject 43 is placed on the top surface of a chuck 42 that holds a wafer and is held by the chuck 42. The chuck 42 is connected to a testing stage 41, which is, for example, a multi-axis stage, and the position of the test subject 43 held by the chuck 42 can be adjusted by driving the testing stage 41.

### Multilayer Wiring Board 12

The multilayer wiring board 12 is a probe board on which a plurality of electrical contactors (probes) are mounted.

A number of bonding members 31, such as solder balls, bond the multilayer wiring board 12 to the center of the bottom surface of the wiring board 11. The multilayer wiring board 12 is, for example, a substantially square board made of an electrically insulating material such as polyimide resin. The multilayer wiring board 12 can be made of a board using resin as the MLO (Multilayer Organic) base material to enable fine wiring.

The bottom surface of the multilayer wiring board 12 has a probe pad area 121 to which a plurality of probes can be attached, and a plurality of wiring paths are formed inside the multilayer wiring board 12. Each wiring path of the multilayer wiring board 12 connects each probe of the probe pad area 121 to a connection terminal provided on the multilayer wiring board 12 for connecting to the wiring board 11.

The probe pad area 121 can be fitted with a plurality of probes for each target device (DUT: device under test) as the test subject 43. For example, FIG. 3 illustrates a case where six probe pad areas 121 are formed on the multilayer wiring board 12. This is because there are six DUTs as the test subject 43, and each probe pad area 121 is arranged to be at the position of the corresponding DUT so that a plurality of probes can electrically contact the respective DUTs. In this way, the probe pad areas 121 are arranged at the positions of the corresponding DUTs, and the plurality of probes in each probe pad area 121 are arranged so that they are in electrical contact with the corresponding DUTs. The probe pad areas 121 are also called probe heads.

Note that although FIG. 3 illustrates an example in which the multilayer wiring board 12 has six probe pad areas 121, the number of probe pad areas 121 is not limited to this. Since the probe pad area 121 is provided for each DUT, the number of probe pad areas 121 is the same as the number of DUTs.

### Wiring Board 11

The wiring board 11 is a board that is connected to the test head of a tester and transmits and receives electrical signals. There are many electrodes on the top surface of the wiring board 11, and the wiring board 11 is connected to the test head via the electrodes on the top surface of the wiring board 11. A wiring pattern is formed on the bottom surface of the wiring board 11, and the wiring board 11 is connected to the multilayer wiring board 12 via the wiring pattern. Furthermore, inside the wiring board 11, wiring paths are formed that connect each terminal on the top surface of the wiring board 11 to each terminal on the bottom surface of the wiring board 11. Therefore, the wiring board 11 has a structure in which each terminal on the top surface and each terminal on the bottom surface can be electrically connected via the internal wiring paths.

On the top surface of the wiring board 11, the reinforcing member 13 and the cover member 14 having the flatness adjustment mechanism 20 are arranged to suppress the deformation of the wiring board 11.

In order to assemble the reinforcing member 13 to the wiring board 11, each of the wiring board 11 and the reinforcing member 13 has a through-hole 531 and a through-hole 532 such as a screw hole that is connected to a fixing member 53. When assembling the wiring board 11 and the reinforcing member 13, the through-hole 531 of the wiring board 11 and the through-hole 532 of the reinforcing member 13 are aligned, and fixing members 53 such as screws are inserted into the through-holes 531 and 532 to be connected, whereby they can be fixed.

### Reinforcing Member 13

The reinforcing member 13 is a member attached to the top surface side of the wiring board 11 in order to suppress deformation, such as bending, of the wiring board 11. The reinforcing member 13 is also called a stiffener.

The reinforcing member 13 is a member having a thickness in the Z direction. The reinforcing member 13 can have various shapes. However, in the present embodiment, for example, as shown in FIG. 3, the reinforcing member 13 has one annular portion and a plurality of radial portions extending radially from the center of the annular portion toward the annular portion. Furthermore, the plurality of radial portions have four inner radial portions extending radially from the center of the annular portion toward the annular portion and eight outer radial portions extending radially from the annular portion toward the outside.

Note that a square frame is provided in the center of the reinforcing member 13 to connect with the square cover member 14 in order to provide the cover member 14 described later. Also, the shape of the reinforcing member 13 is not limited to the shape shown in FIG. 3.

### Cover Member 14

The cover member 14 is attached to the upper side of the reinforcing member 13. The cover member 14 is removable from the reinforcing member 13.

The cover member 14 has the flatness adjustment mechanism 20 that adjusts the flatness of the multilayer wiring board 12 on the bottom surface of the wiring board 11. The cover member 14 also has a function of supporting the load when the probe provided on the multilayer wiring board 12 contacts (when the probe contacts the electrode terminal of the test subject 43).

As illustrated in FIG. 2, the cover member 14 is a square plate-like member that is disposed in the center of the wiring board 11. The square cover member 14 is slightly larger than the multilayer wiring board 12 on the bottom surface of the wiring board 11. The shape of the cover member 14 is not limited to a square.

In order to assemble the cover member 14 to the reinforcing member 13, the reinforcing member 13 and the cover member 14 each have a through-hole 511 and a through-hole 512 such as a screw hole. When assembling the reinforcing member 13 and the cover member 14, the through-hole 511 of the reinforcing member 13 and the through-hole 512 of the cover member 14 are aligned, and fixing members 51 such as screws are inserted into the through-holes 511 and 512, whereby they can be fixed.

### Flatness Adjustment Mechanism 20

The flatness adjustment mechanism 20 of the cover member 14 adjusts the flatness of the multilayer wiring board 12 on the bottom surface of the wiring board 11.

Conventionally, when attaching the multilayer wiring board 12 to the bottom surface of the wiring board 11, a large number of bonding members 31, such as solder balls, are placed in the center of the bottom surface of the wiring board 11. The multilayer wiring board 12 is placed on the large number of bonding members 31 and bonded. When the multilayer wiring board 12 is bonded with the bonding member 31, such as a solder ball, heat is applied, which may cause the multilayer wiring board 12 to warp. Some multilayer wiring boards 12 are warped even before bonding.

If the multilayer wiring board 12 that is warped and has poor flatness is used for testing after bonding to the wiring board 11, the tip positions of the plurality of electrical contactors (probes) may vary (that is, the height of the probes may vary). The contact of the probes with the electrode terminals of the test subject 43 may become poor. In this case, the accuracy of the electrical testing of the test subject 43 may also be affected.

Therefore, in the present embodiment, the cover member 14 is provided with the flatness adjustment mechanism 20 that adjusts the flatness of the multilayer wiring board 12.

After bonding the multilayer wiring board 12 to the bottom surface of the wiring board 11, the flatness adjustment mechanism 20 applies a concentrated load to the multilayer wiring board 12 via the wiring board 11 to correct the warp. In this way, the warping of the wiring board 11 and the multilayer wiring board 12 is suppressed, and variation in the tip positions of the plurality of probes is suppressed. As a result, the contact of the probes with the electrode terminals of the test subject 43 can be improved, and the electrical testing of the test subject 43 can be performed with high accuracy.

The flatness adjustment mechanism 20 of the cover member 14 has one or more indenters 22 that apply a load to the multilayer wiring board 12 via the wiring board 11, and an adjustment member 21 that adjusts the load of each of the one or more indenters 22.

The indenter 22 is a contact member placed on the top surface of the wiring board 11. The indenter 22 is a member that applies a load to the wiring board 11 and the multilayer wiring board 12 after the load is adjusted by the adjustment member 21. That is, the adjustment member 21 adjusts the amount of pressing of the indenter 22 according to the degree of warping of the wiring board 11 and the multilayer wiring board 12, and the indenter 22 applies a load to the wiring board 11 and the multilayer wiring board 12 according to the amount of pressing adjusted by the adjustment member 21. By changing the magnitude of the load, the wiring board 11 and the multilayer wiring board 12 are deformed, and the warping is corrected.

The position of the indenter 22 is preferably selected such that the flatness of the wiring board 11 and the multilayer wiring board 12 is improved and/or the contact between the probe and the DUT is improved.

For example, the indenter 22 is placed at a position corresponding to the center position of the multilayer wiring board 12 (for example, the position of the center of gravity) and a position corresponding to the center position of each probe pad area 121. As in the former case, the multilayer wiring board 12 to be balanced can be supported at the center by placing the indenter 22 at a position corresponding to the center of the multilayer wiring board 12. Also, as in the latter case, the indenter 22 can apply a load to the corresponding probe pad area 121, so that the flatness control can be stabilized and the contact of the probe with the DUT can be improved by arranging the indenter 22 at a position corresponding to the position of the probe pad area 121 (in other words, by providing the indenter 22 for each DUT of the test subject 43).

For example, as shown in FIGS. 2 and 3, when the test subject 43 has six DUTs and the multilayer wiring board 12 has six probe pad areas 121, seven indenters 22 are provided, including one indenter 22 arranged in the center of the multilayer wiring board 12 and six indenters 22 arranged at the respective positions for the six probe pad areas 121.

The indenter 22 comes in various shapes (types), such as a flat cylindrical indenter, a flat prism-shaped indenter, a spherical indenter, and a conical indenter. Various types of indenters can be used as long as they can apply a load to the multilayer wiring board 12 via the wiring board 11. In the present embodiment, the indenter 22 is provided to apply a substantially uniform load to the surface of the probe pad area 121. The material of the indenter 22 is not particularly limited.

The adjustment member 21 adjusts the pressing amount of the corresponding indenter 22. The adjustment member 21 is provided for each indenter 22. The adjustment member 21 fixes the upper part of the indenter 22 and adjusts the pressing amount of the indenter 22 in the vertical direction, and for example, a clamping screw, a screw, or the like can be used. For example, when a clamping screw, a screw, or the like is used as the adjustment member 21, it is possible to adjust how much pressing load can be applied to the indenter 22 by how much rotation.

### Alignment of Indenter 22 in Flatness Adjustment Mechanism 20

Next, the alignment of the indenters 22 in the flatness adjustment mechanism 20 of the cover member 14 will be described.

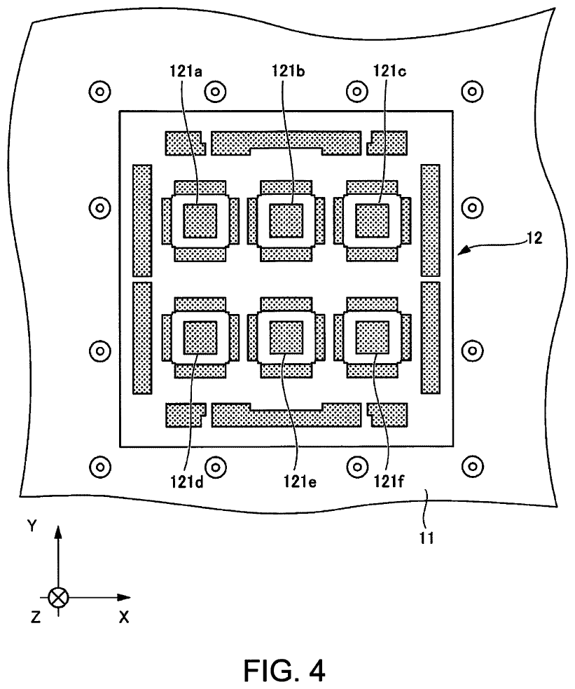

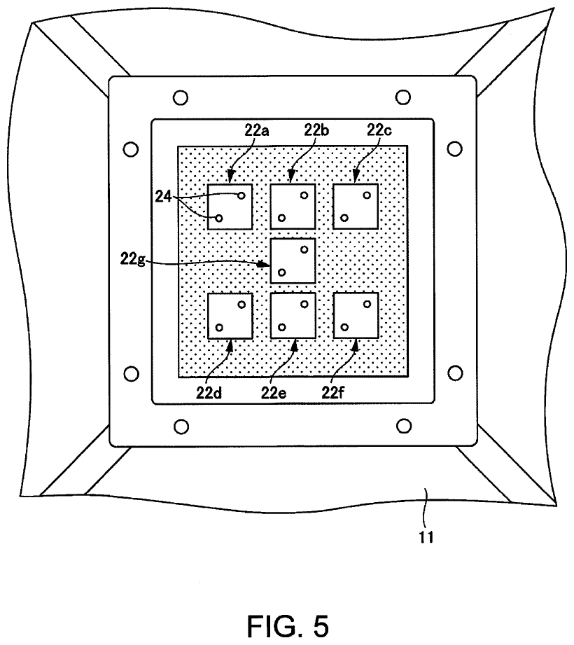

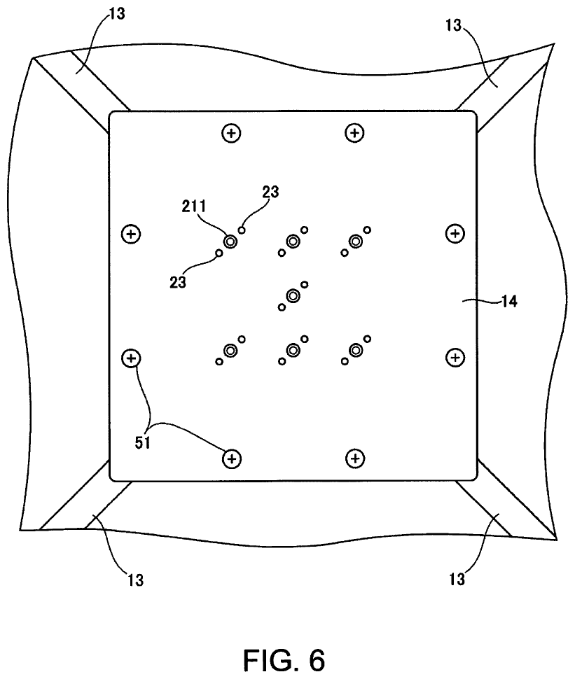

FIG. 4 is a diagram showing the configuration of the multilayer wiring board 12 on the bottom surface of the wiring board 11. FIG. 5 is a diagram showing the arrangement of the indenters 22 on the wiring board 11. FIG. 6 is a diagram showing the configuration of the top surface of the cover member 14 according to the embodiment.

Here, the test subject 43 is assumed to have six DUTs. Therefore, as shown in FIG. 4, the multilayer wiring board 12 having six probe pad areas 121 (121a to 121f) is used. When referring to a specific probe pad area 121, the probe pad area 121 is written as probe pad area 121a and the like.

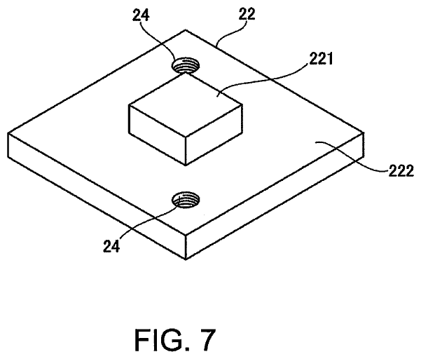

The indenter 22 is assumed to be a flat prism-shaped indenter as shown in FIG. 7. FIG. 7 is a perspective configuration diagram of the indenter 22 as viewed from below. When referring to a specific indenter 22, the indenter 22 is written as indenter 22a and the like.

In FIG. 7, the indenter 22 (22a to 22g) has a pressure receiving portion 222 that receives a pressing pressure from the adjustment member 21, and a flat prism-shaped contact portion 221 that applies a load to the wiring board 11 and the multilayer wiring board 12.

The shape of the contact portion 221 that contacts the wiring board 11 is the same as the shape of the probe pad area 121, and the size of the contact portion 221 is also the same as the size of the probe pad area 121. Due to this, a load can be applied reliably to the probe pad area 121, and as a result, the contact of the probe with the electrode terminal of the test subject 43 can be improved.

In addition, when the indenter 22 applies a load to the wiring board 11 and the multilayer wiring board 12, the tip of the contact portion 221 of the indenter 22 is flattened to distribute the load in order to avoid damage to the wiring board 11 and the multilayer wiring board 12.

An example of the arrangement of the indenters 22 will be described. In this example, as shown in FIG. 5, one indenter 22g of the seven indenters 22 is placed at a position corresponding to the center position (that is, the position of the center of gravity) of the multilayer wiring board 12 in order to achieve balance. The remaining six indenters 22a to 22f are placed at positions corresponding to the centers of the six probe pad areas 121a to 121f of the multilayer wiring board 12, respectively.

As shown in FIG. 6, the cover member 14 has an adjustment hole 211 such as a screw hole for receiving the adjustment member 21 and two positioning holes 23 for each indenter 22 (22a to 22g).

In order to align the indenters 22, the positioning hole 23 of the cover member 14 is aligned with the positioning hole 24 of the corresponding indenter 22, and a fixing member such as a screw is inserted into the positioning hole 23 of the cover member 14 and the positioning hole 23 of the indenter 22. In this manner, the indenters 22 are aligned. Note that the number of positioning holes 24 and positioning holes 23 is not limited to two; it may be one, three, or more, as long as the indenters 22 can be aligned.

When adjusting the magnitude of the load applied by the indenter 22, the adjustment member 21 is inserted into the adjustment hole 211 of the cover member 14.

Here, in regard to the alignment of the indenters 22, in order to enable the contact portion 221 of the indenter 22 to apply the targeted load to the wiring board 11 and the multilayer wiring board 12, the tip portion (lower end portion) of the adjustment member 21 is made to come into contact with the center portion of the pressure receiving portion 222 of the indenter 22 (that is, the position corresponding to the center position of the contact portion 221).

### Flatness Adjustment Method Using Flatness Adjustment Mechanism 20

Next, a flatness adjustment method using the flatness adjustment mechanism 20 of the cover member 14 will be described.

Here, it is assumed that the multilayer wiring board 12 is bonded to the bottom surface of the wiring board 11 using a number of bonding members 31 such as solder balls. It is also assumed that a plurality of probes are attached to each probe pad area 121 of the multilayer wiring board 12, and the reinforcing member 13 is attached to the upper side of the wiring board 11 in a state in which the necessary electronic components are set on the wiring board 11. It is also assumed that the flatness adjustment mechanism 20 is aligned and the cover member 14 is attached to the reinforcing member 13.

In this state, the flatness of the multilayer wiring board 12 bonded to the wiring board 11 is measured, and the flatness adjustment is performed using the flatness adjustment mechanism 20 while determining whether the measured flatness value is equal to or less than a target value. The flatness measurement method is to measure the flatness of the multilayer wiring board 12 using an existing flatness measurement device.

More specifically, for example, in the multilayer wiring board 12, the flatness values at a plurality of arbitrary points are measured in the board region of a certain probe pad area 121, and the pad average flatness value is obtained. Furthermore, the flatness is measured over the entire board surface of the multilayer wiring board 12, and the value with the largest deviation is set as the maximum value. Then, the difference between the maximum value and the area average value is adjusted to be equal to or less than the target value.

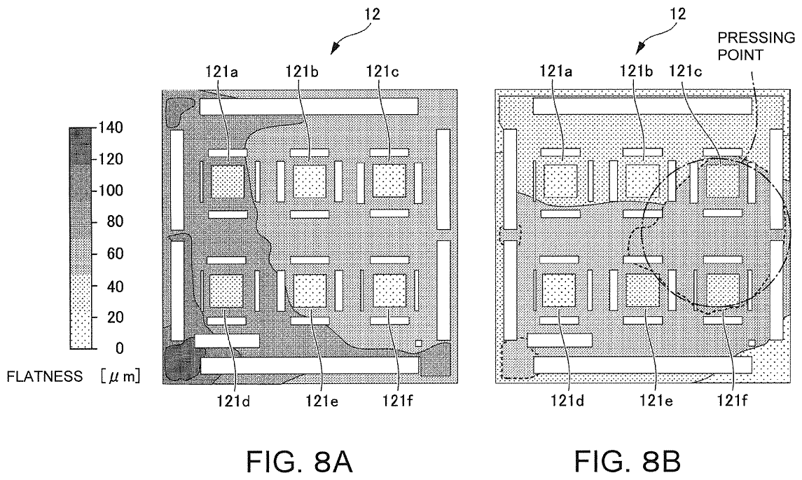

FIG. 8 is a diagram visualizing the flatness measurement result of the multilayer wiring board 12. FIG. 8A illustrates the flatness of the multilayer wiring board 12 before the adjustment by the flatness adjustment mechanism 20, and FIG. 8B illustrates the flatness of the multilayer wiring board 12 after adjustment.

When observing the flatness of the entire board of the multilayer wiring board 12 before adjustment in FIG. 8A, it can be seen that the difference value (the difference value between the maximum value and the area average value described above) near the right end is larger than the difference value on the left side from the center.

Therefore, in order to correct the warping of the entire board of the multilayer wiring board 12, for example, as shown in FIG. 8B, the flatness adjustment mechanism 20 is provided for the probe pad areas 121c and 121f present on the left side of the multilayer wiring board 12 and used. That is, in order to increase the load of the indenters 22c and 22f on the probe pad areas 121c and 121f, the pressing amount of the adjustment members 21 of the indenters 22c and 22f is adjusted to be larger.

As a result, when the indenters 22c and 22f apply a large load to the left side of the multilayer wiring board 12, the multilayer wiring board 12 is deformed, suppressing the warping of the entire board and reducing the flatness value of the entire board (see FIG. 8B).

In addition, the difference in probe height (variation in probe height) provided on the multilayer wiring board 12 before adjustment in FIG. 8A was compared with the difference in probe height provided on the multilayer wiring board 12 after adjustment in FIG. 8B. As a result, it was confirmed that the difference in probe height after adjustment in FIG. 8B was smaller than the difference in probe height before adjustment in FIG. 8A.

### (A-2) Effects of Embodiment

As described above, according to the present embodiment, the cover member 14 is provided with the flatness adjustment mechanism 20 that can apply a plurality of concentrated loads to the multilayer wiring board 12, so that the flatness value of the multilayer wiring board 12 can be adjusted.

As a result, the tip positions of the plurality of probes provided on the multilayer wiring board 12 can be aligned, improving contact with the terminals (DUT) of the test subject 43 and increasing the testing accuracy.

According to the present embodiment, the cover member 14 is removable from the reinforcing member 13, so that the cover member 14 equipped with the flatness adjustment mechanism 20 can be provided on reinforcing members 13 of various shapes as long as it can be placed thereon.

### (B) Other Embodiments

Although various modified examples of the present disclosure were mentioned in the above-described first embodiment, the present disclosure can also be applied to the following modified embodiments.

### (B-1)

In the above-described first embodiment, a case was exemplified in which the shape of the contact portion 221 of the indenter 22 corresponds to the shape of the corresponding probe pad area 121. However, the shape of the contact portion 221 of the indenter 22 is not limited to this.

For example, it is common that a large number of electronic components 6, such as capacitors, are provided on the top surface of the wiring board 11. Therefore, the electronic component 6 may be present at a position corresponding to the probe pad area 121 on the top surface of the wiring board 11 where the indenter 22 is arranged. As a result, the indenter 22 may collide with the electronic component 6. Therefore, the indenter 22 may be configured to apply a load to the probe pad areas 121 of the wiring board 11 and the multilayer wiring board 12 while avoiding collision with the electronic component 6 on the wiring board 11.

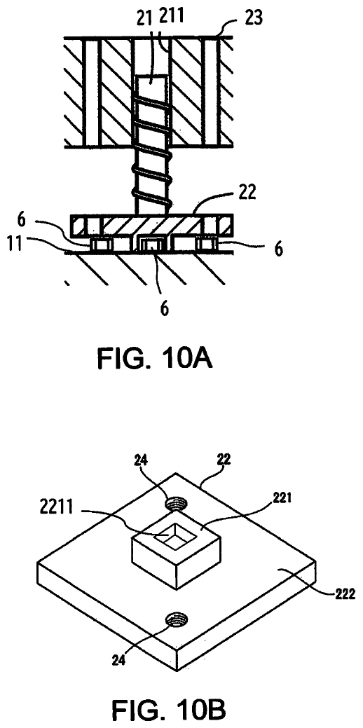

For example, as illustrated in FIG. 10(B), a recess (collision avoidance portion) 2211 may be provided in the center of the contact portion 221 of the indenter 22 to avoid collision with the electronic component 6. As a result, the load can be applied to the wiring board 11 and the multilayer wiring board 12 while avoiding collision between the contact portion 221 of the indenter 22 and the electronic component 6, as shown in FIG. 10(A). Even in this case, the flatness of the wiring board 11 (probe pad area where a plurality of probes are arranged) can be adjusted.

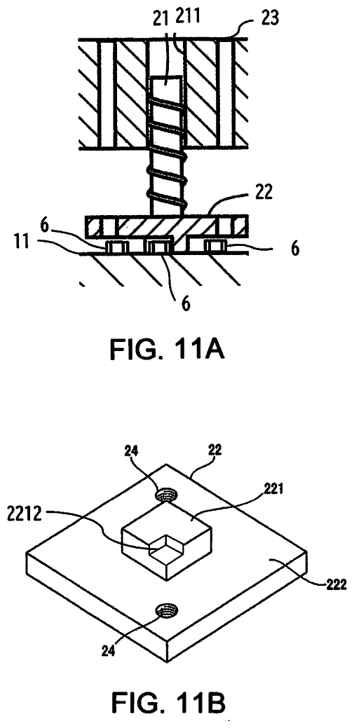

As another modified example, as illustrated in FIG. 11(B), a recess (collision avoidance portion) 2212 may be provided in a partial region of the collision surface of the contact portion 221 of the indenter 22 (in this example, the region including the end of the square collision surface of the contact portion 221). In this case, the same effect can be obtained.

Note that although the recesses (collision avoidance portions) 2211 and 2212 in FIG. 10(B) and FIG. 11(B) are illustrated as being rectangular prism recesses, the shape is not limited as long as it can avoid collision with the electronic component 6, and may be, for example, a cylindrical shape or a polygonal prism.

Note that although the example in FIG. 10(B) and FIG. 11(B) illustrates a case where one recess 2211 or 2212 is provided in the contact portion 221 of the indenter 22, two or more recesses may be provided. Furthermore, the recess 2211 or 2212 is not necessary on all the indenters 22; it may be provided on some of the indenters 22 that collide with the electronic component 6.

### (B-2)

In the above-described first embodiment, a case was exemplified in which the cover member 14 is provided on the reinforcing member 13. However, the arrangement of the cover member 14 is not limited to this. For example, the cover member 14 may be arranged on the top surface of the multilayer wiring board 12 as long as it is possible to adjust the flatness of the multilayer wiring board 12 as a probe board (or the flatness of each probe pad area 121 of the multilayer wiring board 12).

### REFERENCE SIGNS LIST

10 Electrical connecting apparatus
11 Wiring board
12 Multilayer wiring board
13 Reinforcing member
14 Cover member
20 Flatness adjustment mechanism
21 Adjustment member
22 (22a to 22g) Indenter
211 Adjustment hole
221 Contact portion
2211 and 2212 Recess (collision avoidance portion)
222 Pressure receiving portion
23 Positioning hole
24 Positioning hole
31 Bonding member
41 Testing stage
42 Chuck
43 Test subject
51 Fixing member
53 Fixing member
100 Probe card
121 (121a to 121f) Probe pad area
511 Through-hole
512 Through-hole
531 Through-hole
532 Through-hole

1. An electrical connecting apparatus comprising:
a wiring board electrically connected to a testing device;
a probe board provided on a bottom surface side of the wiring board and having one or more probe attachment parts on which a plurality of probes are mounted for each electrode terminal of a test subject that has one or more electrode terminals, the plurality of probes being electrically contacted with the corresponding electrode terminals; and
a cover member that adjusts flatness of the probe board and has at least one or more flatness adjustment mechanisms provided corresponding to each of the probe attachment parts of the probe board.

2. The electrical connecting apparatus according to claim 1, wherein
each of the flatness adjustment mechanisms comprises:
a contact member placed on a top surface of the wiring board to apply a load to the probe board through the wiring board; and
an adjustment member that adjusts the load applied by the contact member to the probe board.

3. The electrical connecting apparatus according to claim 2, wherein
the adjustment member adjusts the load of the contact member by adjusting the pressure on the contact member on the wiring board.

4. The electrical connecting apparatus according to claim 2, wherein
the contact member has a contact portion that contacts the wiring board and a pressure receiving portion that transmits pressure from the adjustment member to the contact portion, and
a shape of the contact portion corresponds to a shape of the probe attachment portion.

5. The electrical connecting apparatus according to claim 2, wherein
the contact member has a contact portion that contacts the wiring board and a pressure receiving portion that transmits pressure from the adjustment member to the contact portion, and
the contact portion has a collision avoidance portion that avoids collision with electronic components on the wiring board.

6. The electrical connecting apparatus according to claim 1, further comprising:
a reinforcing member provided on a top surface side of the wiring board, wherein
a space is provided in a center of the reinforcing member on the wiring board, and the cover member having one or more of the flatness adjustment mechanisms is provided in the center of the reinforcing member.

7. The electrical connecting apparatus according to claim 1, wherein
the cover member having the flatness adjustment mechanism is removable from the reinforcing member.

8. The electrical connecting apparatus according to claim 1, wherein
the cover member is provided with the flatness adjustment mechanism for each of the probe attachment parts at the corresponding position of each of the probe attachment parts and the flatness adjustment mechanism at a position corresponding to a center of gravity of the probe board.
